(19) United States
(12) Patent Application Publication
(10) Pub. No.: US 2008/0111192 A1
(43) Pub. Date: May 15, 2008

(54) HIGH-VOLTAGE-WITHSTANDING SEMICONDUCTOR DEVICE AND FABRICATION METHOD THEREOF

(75) Inventor: Osamu Koike, Miyagi (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Tokyo (JP)

(21) Appl. No.: 11/875,023

(22) Filed: Oct. 19, 2007

(30) Foreign Application Priority Data
Nov. 10, 2006 (JP) 2006305991

(51) Int. Cl. H01L 27/06; H01L 21/8234

(52) U.S. Cl. 257/356; 438/237; 257/E27.016; 257/E21.616

(57) ABSTRACT

There is provided a high-voltage-withstanding semiconductor device a fabrication method thereof capable of suppressing Vt fluctuation induced by plasma damage in a via hole forming step. In the high-voltage-withstanding semiconductor device, a gate electrode of a transistor having a gate insulating film formed on a semiconductor substrate and having a thickness of 350 Å or more and a diode composed of a first conductive well region formed in a surface layer region of the semiconductor substrate and a second conductive diffusion layer formed in the surface layer region of the semiconductor substrate and on the well region are electrically connected by a wire directly connected to contacts formed respectively on the gate electrode and the diode, via the contacts.

### CROSS-REFERENCE TO RELATED APPLICATION

This application claims priority under 35 USC 119 from Japanese Patent Application No. 2006-305991, the disclosure of which is incorporated by reference herein.

### BACKGROUND OF THE INVENTION

1. Field of the Invention

The present invention relates to a high-voltage-withstanding semiconductor device and a method for fabricating the high-voltage-withstanding semiconductor device.

2. Description of Related Art

Conventionally, contacts for electrically connecting respective layers are formed in methods for fabricating a semiconductor device having a multi-layered wiring substrate. These contacts are formed normally in a way of forming contact holes by dry etching such as plasma etching and of embedding conductors therein.

A gate insulating film of the semiconductor device is susceptible to plasma damage during the plasma etching and is more susceptible to the plasma damage due to thinning of the gate insulating film in recent. Therefore, there have been proposed many methods for reducing the plasma damage in the semiconductor device having the thin gate insulating film. However, no attention has been paid to a need for avoiding plasma damage in a high-voltage-withstanding semiconductor device that requires a thick gate insulating film (see Japanese Patent Application Laid-open No. 2000-260987 for example).

FIG. 5 shows a structure of a prior art semiconductor device. A gate insulating film 76 and a gate electrode 77 are formed on a semiconductor substrate 75, and source and drain regions 78 and 79 are formed at a surface layer region of the semiconductor substrate 75 on the both sides of the gate electrode 77. The source region 78, the drain region 79 and the gate electrode 77 are connected to first metal wires 81 via contacts 80. The first metal wires 81 are connected to second metal wires 83 via first via holes 82 and the second metal wires 83 are connected to third metal wires 85 via second via holes 84. The gate electrode 77 is insulated from the first metal wire 81 by an intermediary film 86, the first metal wires are insulated from the second metal wires 83 by a first interlayer film 87 and the second metal wires 83 are insulated from the third metal wires 85 by a second interlayer film 88.

Thus, it is the present state of the high-voltage-withstanding semiconductor device not to take any countermeasure against the plasma damage.

However, the high-voltage-withstanding semiconductor device having the thick gate insulating film generates Vt fluctuation due to the plasma damage. Therefore, it is necessary to take a countermeasure for suppressing the Vt fluctuation. Specifically, it can be seen from FIG. 6 that the Vt fluctuation sharply rises from around 350 Å of the thickness of the gate insulating film as the thickness increases in the transistor shown in FIG. 5. Therefore, it is necessary to take a countermeasure against the plasma damage to suppress the Vt fluctuation in the high-voltage-withstanding semiconductor device in which the thickness of the gate insulating film is 350 Å or more.

Furthermore, in the transistor shown in FIG. 5, an area ratio of a total opening area of the contact hole formed on the gate electrode to an area of a part of the gate electrode contacting with the gate insulating film is proportional to the Vt fluctuation as shown in FIG. 7 and Vt fluctuation of around 0.07 V is generated in forming the contact holes. Accordingly, in order to avoid an operational trouble of the high-voltage-withstanding semiconductor device, it is necessary to suppress dispersion of the Vt fluctuation by equalizing the area ratios of the total opening area of the contact holes to the part of area of the gate electrode contacting with the gate insulating film among the plurality of transistors.

### SUMMARY OF THE INVENTION

The present invention has been made in view of the problems described above and achieves the following object.

That is, the object of the invention is to provide a high-voltage-withstanding semiconductor device capable of suppressing Vt fluctuation induced by plasma damage in a step of forming via holes, and a method for fabricating the same.

As a result of an ardent study, the inventors have found that the use of the following high-voltage-withstanding semiconductor device and the method for fabricating the high-voltage-withstanding semiconductor device solve the prior art problems, and thus achieved the aforementioned object.

That is, a high-voltage-withstanding semiconductor device of a first aspect of the invention provides a high-voltage-withstanding semiconductor device, wherein a gate electrode of a transistor having a gate insulating film formed on a semiconductor substrate and having a thickness of 350 Å or more and a diode composed of a first conductive well region formed in a surface layer region of the semiconductor substrate and a second conductive diffusion layer formed in the surface layer region of the semiconductor substrate and on the well region are electrically connected by a wire directly connected to contacts formed respectively on the gate electrode and the diode, via the contacts.

According to the high-voltage-withstanding semiconductor device of the first aspect of the invention, a flow of charge (electric current) generated in forming via holes on the wiring layer by means of plasma etching flows through the diode whose electric resistance is low as compared to the gate insulating film and does not flow through the gate electrode. Therefore, the first aspect of the invention enables the gate insulating film to avoid the influence of the plasma damage that is otherwise caused by the current generated during the plasma etching and can suppress the Vt fluctuation.

A high-voltage-withstanding semiconductor device of a second aspect of the invention provides a high-voltage-withstanding semiconductor device, including: a semiconductor substrate; transistors each having a first conductive channel region formed in a surface layer region of the semiconductor substrate, second conductive source and drain regions formed on both sides of the channel region, a gate insulating film formed on the channel region and having a thickness of 350 Å or more and a gate electrode formed on the gate insulating film; a diode composed of a first conductive well region formed in the surface layer region of the semiconductor substrate and a second conductive diffusion layer formed in the surface layer region of the semiconductor substrate and on the well region; contacts formed respectively on the gate electrode and on the second conductive diffusion layer; and a wire, formed in the same wiring layer on the respective contacts, for electrically connecting the respective contacts.

Furthermore, a method for fabricating a high-voltage-withstanding semiconductor device of a fourth aspect of the invention provides a method for fabricating a high-voltage-withstanding semiconductor device, including: preparing a semiconductor substrate having a first conductive transistor forming region and a first conductive diode forming region; forming a transistor by forming a first conductive channel region in a surface layer region of the semiconductor substrate in the transistor forming region, forming a gate insulating film having a thickness of 350 Å or more on the channel region, forming a gate electrode on the gate insulating film and forming second conductive source and drain regions on both sides of the channel region; forming a diode by forming a second conductive diffusion layer in the surface layer region of the semiconductor substrate in the diode forming region; forming contacts respectively on the gate electrode and on the second conductive diffusion layer; and forming a wire for electrically connecting the respective contacts in the same wiring layer on the respective contacts.

According to the second and fourth aspects of the invention, an electric current generated in forming via holes to on the wiring layer by means of plasma etching flows through the diode, so that it becomes possible to avoid the plasma damage in the gate insulating film that has been generated in the prior art high-voltage-withstanding semiconductor device. Furthermore, because the contact on the gate insulating film and the contact on the diode are connected by the wire formed in the same wiring layer, the gate insulating film may be readily connected with the diode by a step of forming a wiring layer of the prior art high-voltage-withstanding semiconductor device.

In a high-voltage-withstanding semiconductor device of a third aspect of the invention, a difference in area ratios of an area of a part of the gate electrode contacting with the gate insulating film to a total opening area of contact holes formed on the gate electrode among the transistors having the gate oxide film of a thickness of 350 Å or more falls within a range of −5.0% to 5.0%.

According to the high-voltage-withstanding semiconductor device of the third aspect of the invention, a difference in area ratio of a total opening area of contact holes to an area of a part of the gate electrode contacting with the gate insulating film is designed to fall within a predetermined range among a plurality of transistors existing in the high-voltage-withstanding semiconductor device, so that the plasma damage generated in forming the contact holes is equally applied to the plural transistors. Due to this, the Vt fluctuation generated in forming the contact holes is equalized among the plural transistors. Accordingly, it becomes possible to suppress the dispersion of the Vt fluctuation among the transistors and to avoid an operational failure from occurring in the high-voltage-withstanding semiconductor device due to the dispersion of the threshold value Vt that may otherwise occur among the transistors.

Thus, the invention can provide the high-voltage-withstanding semiconductor device capable of suppressing the Vt fluctuation induced by the plasma damage in the step of forming the via holes, and the method for fabricating the same.

### BRIEF DESCRIPTION OF THE DRAWINGS

Preferred exemplary embodiments of the present invention will be described in detail with referenced to the following figures, wherein:

FIG. 1 is a schematic diagram of a high-voltage-withstanding semiconductor device using a NMOS transistor according to an embodiment of the invention;

FIG. 2 is a schematic diagram of a high-voltage-withstanding semiconductor device using a PMOS transistor according to the embodiment of the invention;

FIG. 3 is a diagram showing a route of an electric current generated during plasma etching of the embodiment in the high-voltage-withstanding semiconductor device using the NMOS transistor of the embodiment of the invention;

FIG. 4 is a diagram showing a route of an electric current generated during plasma etching of the present embodiment in the high-voltage-withstanding semiconductor device using the PMOS transistor of the embodiment of the invention;

FIG. 5 is a partial section view showing a prior art high-voltage-withstanding semiconductor device; FIG. 6 is a graph showing dependency of Vt fluctuation on a thickness of a gate insulating film of the prior art high-voltage-withstanding semiconductor device and the high-voltage-withstanding semiconductor device of the invention after forming via holes; and

FIG. 7 is a graph showing dependency of Vt fluctuation on an area ratio of a total opening area of contact holes to an area of a part of the gate electrode contacting with the gate insulating film after forming the via holes.

### DETAILED DESCRIPTION OF THE INVENTION

One exemplary embodiment of a high-voltage-withstanding semiconductor device of the invention and its fabrication method will be explained below with reference to the drawings.

### <High-Voltage-Withstanding Semiconductor Device and Fabrication Method Thereof>

### [NOMS Transistor]

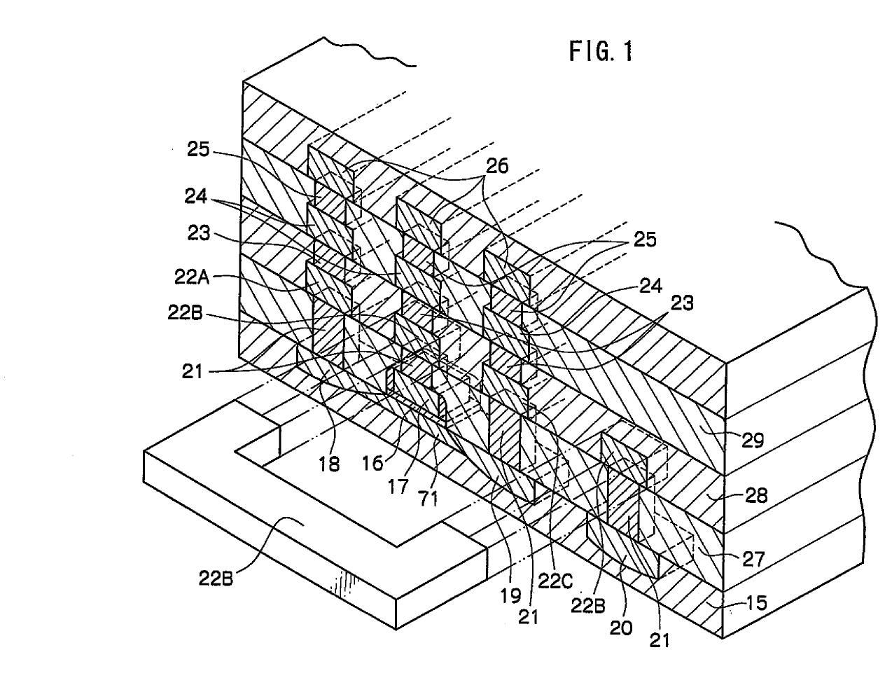

FIG. 1 is a schematic diagram of a high-voltage-withstanding semiconductor device using a NMOS transistor of the invention.

The high-voltage-withstanding semiconductor device is fabricated through the following processing steps.

### <Steps for Preparing Semiconductor Substrate>

A semiconductor substrate having a first conductive transistor forming region and a first conductive diode forming region in a surface layer region thereof is prepared.

Here, the first conductive transistor forming region is formed at a region different from the first conductive diode-forming region. A distance between the transistor forming region and the diode forming region is not specifically defined as long as they are apart from each other by a degree of exhibiting functions of transistor and diode, respectively.

### <Step for Forming Transistor and Step for Forming Diode>

The transistor is formed through processing steps of forming a first conductive p-channel region 71 in a surface layer region of the semiconductor substrate in the transistor forming region, forming a gate insulating film 16 whose thickness is 350 Å or more on the p-channel region 71, forming a gate electrode 17 on the gate insulating film 16 and forming second conductive source region 18 and drain region 19 on the both sides of the p-channel region 71.

The diode is formed through a processing step of forming a second conductive n diffusion layer 20 in the surface layer region of the semiconductor substrate in the diode forming region.

Here, it is preferable to form the second conductive source region 18 and drain region 19 in the surface layer region of the semiconductor substrate in the transistor forming region concurrently with the second conductive n⁺ diffusion layer 20 to be formed in the surface layer region of the semiconductor substrate in the diode forming region. It is preferable because a number of steps and fabrication time for forming the diode may be suppressed.

A conventional method such as ion implantation may be used as the method for forming the second conductive source region 18, drain region 19 and the n⁺ diffusion layer 20.

### <Step for Forming Contact>

Contacts 21 are formed on the gate electrode 17 and the n⁺ diffusion layer 20, respectively.

The contacts 21 are formed through the following processing steps. At first, an intermediary film 27 is stacked after forming the transistor and diode. Next, contact holes are formed so that they penetrate to the gate electrode 17, the source region 18, the drain region 19 and the n⁺ diffusion layer 20, and conductors are embedded in the contact holes. Here, the contact holes may be formed through prior art etching methods such as dry etching or wet etching.

### <Step for Forming Wires that Electrically Connect Contacts>

In the high-voltage-withstanding semiconductor device of the invention, the gate electrode 17 of the transistor having the gate insulating film 16 whose thickness is 350 Å or more formed on the semiconductor substrate and the diode composed of a first conductive p-well region 15 formed in the surface layer region of the semiconductor substrate and the second conductive n⁺ diffusion layer 20 formed on the p-well region 15 in the surface layer region of the semiconductor substrate are electrically connected via the contacts 21, formed respectively thereon, by a wire directly connected to the contacts 21. The connection form of the wire electrically connecting the contact 21 formed on the gate electrode 17 and the contact 21 formed on the second conductive n⁺ diffusion layer 20 is not specifically defined as long as it electrically and directly connect them without going through other wires. Furthermore, a barrier film of Ti or TiN may be interposed on the contact 21 and under the wire.

In the high-voltage-withstanding semiconductor device of the invention, the wire connecting the contact 21 formed on the gate electrode 17 and the contact 21 formed on the n⁺ diffusion layer 20 is formed in the same and one wiring layer. It is possible to suppress an increase of a number of fabrication steps and fabrication time when the contacts 21 and the wire are formed in the same wiring layer. In FIG. 1, the contact 21 formed on the gate electrode 17 is electrically connected with the contact 21 formed on the n⁺ diffusion layer 20 by a first metal wire 22B. Furthermore, a first metal wire 22A is connected with the source region 18 via the contact 21 and a first metal wire 22C is connected with the drain region 19 via the contact 21.

### <Other Steps>

The metal wires 22A, 22B and 22C are connected with second metal wires 24 via first via holes 23 and the second metal wires 24 are connected with third metal wires 26 via second via holes 25.

The high-voltage-withstanding semiconductor device of the invention fabricated through the processing steps described above can avoid plasma damage that otherwise occurs in forming the via holes 23 and 25. It can be seen from FIG. 6 that while the Vt fluctuation increases when the thickness of the gate insulating film is 350 Å or more in the prior art high-voltage-withstanding semiconductor device in which no diode is formed, the Vt fluctuation does not increase in the high-voltage-withstanding semiconductor device of the invention in which the diode is formed.

As one aspect, a difference in area ratios of an area of a part of the gate electrode 17 contacting with the gate insulating film 16 to a total opening area of the contact hole formed on the gate electrode 17 among the respective transistors is preferable to be in a range of −5.0% to 5.0%. When the difference in area ratios is within this range, it becomes possible to suppress the dispersion of the Vt fluctuation among the transistors that is the cause of the plasma damage in forming the contact holes and to suppress erroneous operations of the high-voltage-withstanding semiconductor device.

Here, the term “total opening area” represents a sum of opening areas of the contact holes formed on one gate electrode. When one contact hole is formed on one gate electrode, for example, an opening area of that one contact hole correspond to the “total opening area”. When two contact holes are formed on one gate electrode, for example, a sum of opening areas of the two contact holes corresponds to the “total opening area”.

Here, the term “difference in area ratios” is represented by [((A)−(B))×100/(B)] (%), wherein (A) is an area ratio of the total opening area of the plurality of contact holes located on the gate electrode in each transistor existing in the high-voltage-withstanding semiconductor device to the part of the area of the gate electrode 17 contacting with the gate insulating film 16 and (B) is an average value of the area ratio of the total opening area of the plurality of contact holes located on the gate electrode of each transistor existing in the high-voltage-withstanding semiconductor device to the part of the area of the gate electrode 17 contacting with the gate insulating film 16.

It is noted that although FIG. 1 shows a configuration such that the contact 21 on the gate electrode is located in an active region, a preferable aspect of the high-voltage-withstanding semiconductor device of the invention is to draw out the gate electrode 17 to the region other than the active region composed of the source region 18, the drain region 19 and the p-channel region 71 under the gate insulating film and to form the contact 21 on the drawn gate electrode 17.

It is possible to use conventional oxides such as a nitrogen oxide film for the gate insulating film 16 in FIG. 1. Conventional metals such as Poly Si, WSiX and W may be used for the gate electrode 17. Conventional metals such as Poly-Si, Al, W and Cu may be used for the contact 21, the first via hole 23 and the second via hole 25. Conventional alloys such as Al—Cu alloy, A-Cu—Si and Cu may be used for the first metal wires 22A, 22B and 22C, the second metal wire 24 and the third metal wire 26. The conventional oxides such as SiO₂ may be used for the intermediary layer 27, the first and second interlayer films 28 and 29.

As for the thickness of the gate insulating film 16, the result of the prior art example in FIG. 6 shows that the Vt fluctuation sharply increases when the thickness is 350 Å or more. Accordingly, the high-voltage-withstanding semiconductor device of the invention that can suppress the plasma damage in forming the first via hole 23 and the plasma damage in forming the contact holes brings about the effect of the invention when the thickness of the gate insulating film 16 is 350 Å or more. Furthermore, the invention enables the thickness of the gate insulating film 16 to be appropriately changed according to its use when the thickness is 350 Å or more.

The formation the via holes in forming the contacts 21, the first via hole 23 and the second via hole 25 may be conducted by plasma etching and the like. The plasma etching may be carried out by using prior art etching gases such as CF gases like CF₄, C₄F₈, C₅F₈ and CHF₃, Ar and mixed gas of O₂ as a condition of plasma etching.

The source region 18, the drain region 19 and the n⁺ diffusion layer 20 may be formed by prior art methods such as ion implantation.

### [PMOS Transistor]

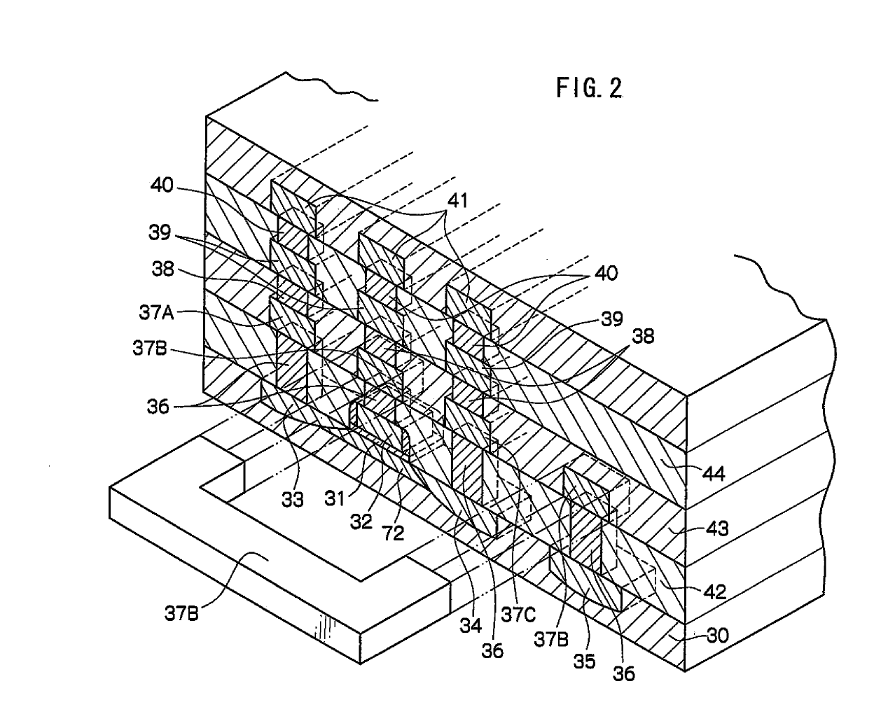

FIG. 2 is a schematic diagram of a high-voltage-withstanding semiconductor device using a PMOS transistor of the invention.

The high-voltage-withstanding semiconductor device is fabricated through the following processing steps.

### <Steps for Preparing Semiconductor Substrate>

A semiconductor substrate having a first conductive transistor forming region and a first conductive diode forming region in a surface layer region thereof is prepared.

Here, the first conductive transistor forming region is formed at a region different from the first conductive diode-forming region. A distance between the transistor forming region and the diode forming region is not specifically defined as long as they are apart from each other by a degree of exhibiting functions of transistor and diode, respectively.

### <Step for forming Transistor and Step for forming Diode>

The transistor is formed through processing steps of forming a first conductive n-channel region 72 in a surface layer region of the semiconductor substrate in the transistor forming region, forming a gate insulating film 31 whose thickness is 350 Å or more on the n-channel region 72, forming a gate electrode 32 on the gate insulating film 31 and forming second conductive source region 33 and drain region 34 on the both sides of the n-channel region 72. The diode is formed through a processing step of forming a second conductive p⁺ diffusion layer 35 in the surface layer region of the semiconductor substrate in the diode forming region.

Here, it is preferable to form the second conductive source region 33 and drain region 34 in the surface layer region of the semiconductor substrate in the transistor forming region concurrently with the second conductive p⁺ diffusion layer 35 to be formed in the surface layer region of the semiconductor substrate in the diode forming region. It is preferable because a number of steps and fabrication time for forming the diode may be suppressed.

A conventional method such as ion implantation may be used as the method for forming the second conductive source region 33 and drain region 34 and the p⁺ diffusion layer 35.

### <Step for forming Contacts>

Contacts 36 are formed on the gate electrode 32 and the second conductive p⁺ diffusion layer 35, respectively.

The contacts 36 are formed through the following processing steps. At first, an intermediary film 42 is stacked after forming the transistor and diode. Next, contact holes are formed so that they penetrate to the gate electrode 32, the source region 33, the drain region 34 and the p⁺ diffusion layer 35 and conductors are embedded to the contact holes. Here, the contact holes may be formed through prior art etching methods such as dry etching or wet etching.

### <Step for forming Wire that Electrically Connect Contacts>

In the high-voltage-withstanding semiconductor device of the invention, the gate electrode 32 of the transistor having the gate insulating film 31 whose thickness is 350 Å or more formed on the semiconductor substrate and the diode composed of a first conductive n-well region 30 formed in the surface layer region of the semiconductor substrate and the second conductive p⁺ diffusion layer 35 formed on the n-well region 30 in the surface layer region of the semiconductor substrate are electrically connected via the contacts 36, formed respectively thereon, by a wire directly connected to the contacts 36. The connection form of the wire electrically connecting the contact 36 formed on the gate electrode 32 and the contact 36 formed on the second conductive p⁺ diffusion layer 35 is not specifically defined as long as it electrically and directly connect them without going through other wires. Furthermore, a barrier film of Ti or TiN may be interposed on the contact 36 and under the wire.

In the high-voltage-withstanding semiconductor device of the invention, the wire connecting the contact 36 formed on the gate electrode 32 and the contact 36 formed on the second conductive p⁺ diffusion layer 35 is formed in the same wiring layer. It is possible to suppress an increase of a number of fabrication steps and fabrication time when the wire is formed on the same wiring layer. In FIG. 2, the contact 36 formed on the gate electrode 32 is electrically connected with the contact 36 formed on the p⁺ diffusion layer 35 by a first metal wire 37B formed in the same wiring layer. Furthermore, a first metal wire 37A is connected with the source region 33 via the contact 36 and a first metal wire 37C is connected with the drain region 34 via the contact 36.

### <Other Steps>

The metal wires 37A, 37B and 37C are connected with second metal wires 39 via first via holes 38 and the second metal wires 39 are connected with third metal wires 26 via second via holes 40.

The high-voltage-withstanding semiconductor device of the invention fabricated through the processing steps described above can avoid plasma damage that otherwise occurs in forming the first via holes 38 and the second via holes 40. While FIG. 6 shows the result of the NMOS transistor, the PMOS transistor also shows the same tendency and the Vt fluctuation does not increase in the high-voltage-withstanding semiconductor device of the invention in which the diode is formed.

A difference in the area ratios of the area of the part of the gate electrode 32 contacting with the gate insulating film 31 to the total opening area of the contact holes formed on the gate electrode 32 among the respective transistors is preferable to be in a range of −5.0% to 5.0%. When the difference in the area ratios is within this range, it becomes possible to suppress the dispersion of the Vt fluctuation among the transistors that is the cause of the plasma damage in forming the contact holes and to suppress erroneous operations of the high-voltage-withstanding semiconductor device.

Here, the terms “difference in area ratios” and “total opening area” have the same meaning with those described above.

It is noted that although FIG. 2 shows such that the contact 36 on the gate electrode is located in an active region, it is preferable to draw out the gate electrode 32 to the region other than the active region composed of the source region 33, the drain region 34 and the n-channel region 72 under the gate insulating film and to form the contact 36 on the drawn gate electrode 32.

It is possible to use conventional oxides such as a nitrogen oxide film for the gate insulating film 31 in FIG. 2. Conventional metals such as Poly Si, WSIX and W may be used for the gate electrode 32. Conventional metals such as Poly-Si, Al, W and Cu may be used for the contact 36, the via hole 38 and the via hole 40. Conventional alloys such as Al—Cu alloy, A-Cu—Si and Cu may be used for the first metal wires 37A, 37B and 37C, the second metal wire and the third metal wire 26. The conventional oxides such as SiO₂ may be used for the intermediary layer 27 and the interlayer films 43 and 44.

As for the thickness of the gate insulating film 31, as FIG. 6 shows the Vt fluctuation of the NMOS transistor and the PMOS transistor also shows the same tendency, the high-voltage-withstanding semiconductor device of the invention brings about the effect of the invention when the thickness of the gate insulating film 31 is 350 Å or more. Furthermore, the invention enables the thickness of the gate insulating film 16 to be appropriately changed according to its use when the thickness is 350 Å or more.

The formation of the contact holes in forming the contacts 36, the first via hole 38 and the second via hole 40 may be conducted by plasma etching and the like. The plasma etching may be carried out by using conventional etching gases such as CF gases like CF₄, C₄F₈, C₅F₈ and CF₃,Ar and mixed gas of O₂.

The source region 33, the drain region 34 and the p⁺ diffusion layer 35 may be formed by conventional methods such as ion implantation.

The gate electrode 32 of the high-voltage-withstanding semiconductor device using the PMOS transistor described in FIG. 2 is directly connected to the n⁺ diffusion layer 35 via the contacts 36 and the first metal wire 37B. This arrangement is made so as not to flow a current generated in forming first via hole to the gate electrode 32 and it enables one to suppress the Vt fluctuation of the gate insulating film 31.

It is noted that FIG. 2 shows such that the contact 36 on the gate electrode is located in the active region. However, it is preferable to form the contact 36 in a region other than the active region composed of the source region 33, the drain region 34 and the n-channel region 72 under the gate insulating film and on the gate electrode 32.

### [Operation of Forward Diode in First Via Hole Etching Step in NMOS Transistor]

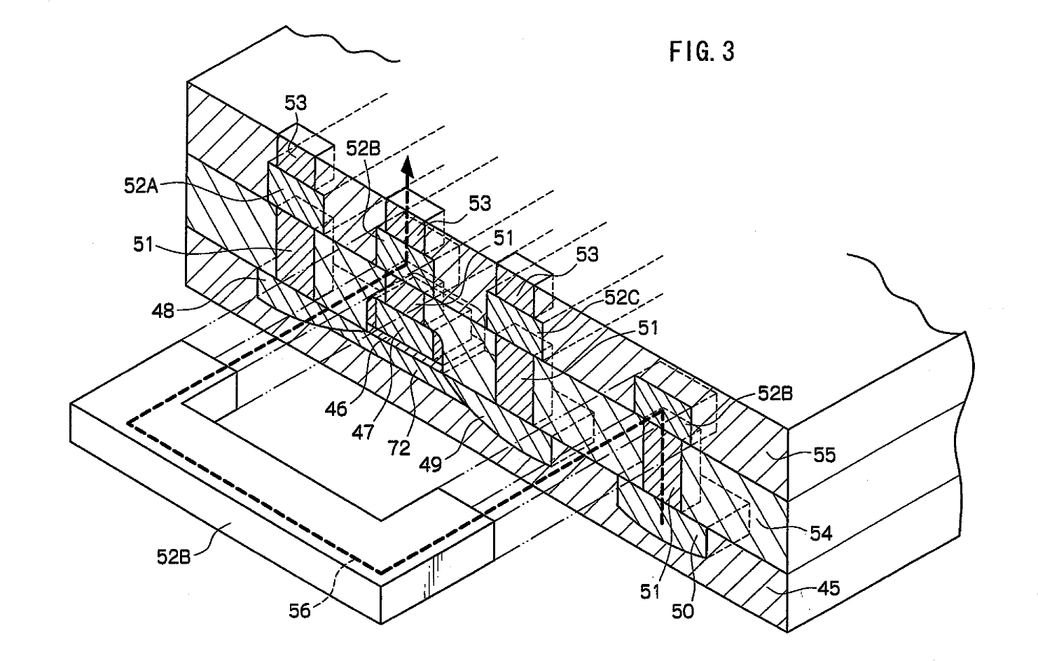

FIG. 3 shows operations in the first via hole etching step in the high-voltage-withstanding semiconductor device using the NMOS transistor of the invention.

In the high-voltage-withstanding semiconductor device using the NMOS transistor of the invention, a diode is formed as shown in FIG. 3 by forming a gate insulating film 46 and a gate electrode 47 on a p-well region 45, forming a source region 48 and a drain region 49 on the surface of the p-well region on the both sides of the gate electrode 47 and providing a n⁺ diffusion layer 50 in a region other than an active region composed of the source region 48, the drain region 49 and a p-channel region 73 under the gate insulating film 46.

Next, an intermediary layer 54 is deposited on the substrate on which the gate electrode 47 has been formed and contacts 51 are provided after forming contact holes by a method such as plasma etching.

The source region 48 is connected to a first metal wire 52A via the contact 51, the drain region 49 is connected to a first metal wire 52C via the contact 51 and gate electrode 47 and the n⁺ diffusion layer 50 are connected to a first metal wire 52B via the contact 51.

First via holes 53 are formed on the first metal wires 52A, 52B and 52C.

The gate electrode 47 is insulated from the first metal wires 52A, 52B and 52C by the intermediary film 54 and the first metal wires 52A, 52B and 52C and the first via hole 53 are covered by the first interlayer film 55.

In the high-voltage-withstanding semiconductor device of the invention, the gate electrode 47 is directly connected with a forward diode 57 via the contact 51 and the first metal wire 52B.

An electric current 56 generated during the plasma etching enters from the forward diode 57 and passes in order of the contact 51 on the forward diode 57 and the first metal wire 52B. Accordingly, the current generated during the plasma etching does not pass through the gate electrode 47, so that it is possible to avoid the influence of the plasma damage that is the cause of the Vt fluctuation.

### [Operation of Forward Diode in First Via Hole Etching Step in PMOS Transistor]

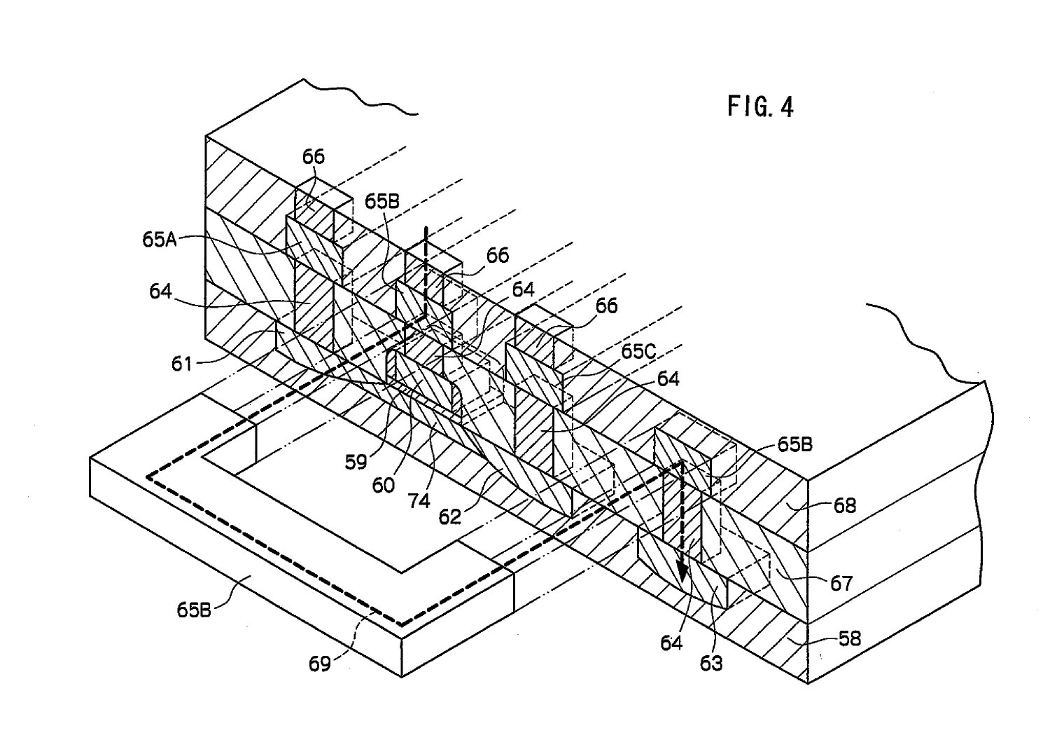

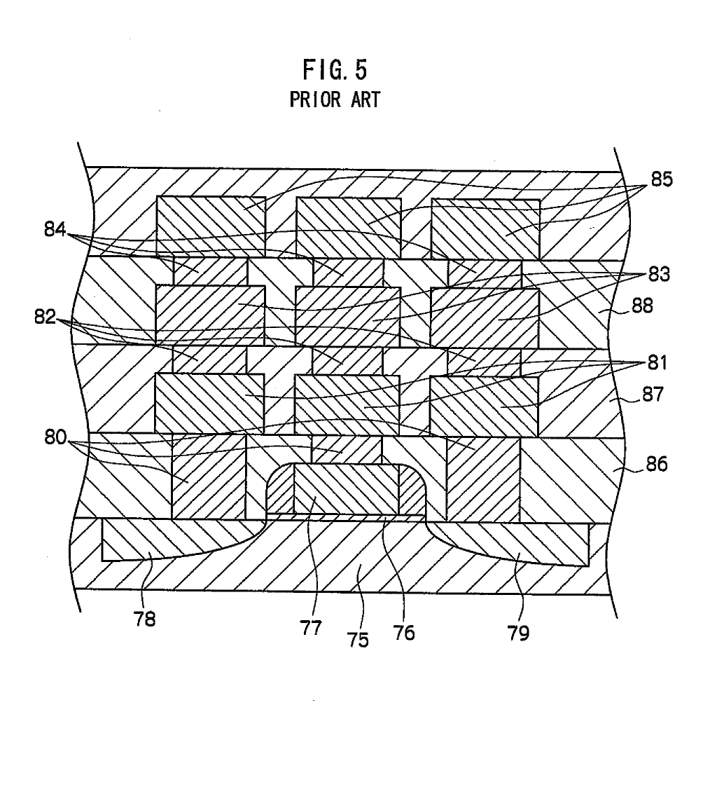

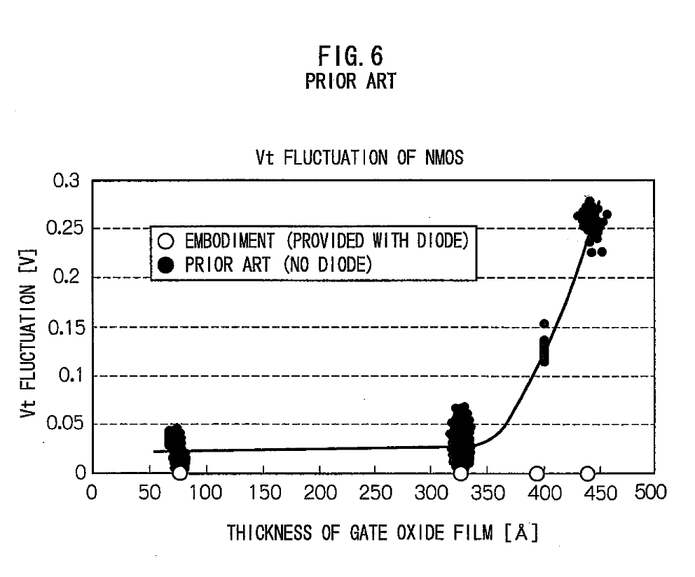

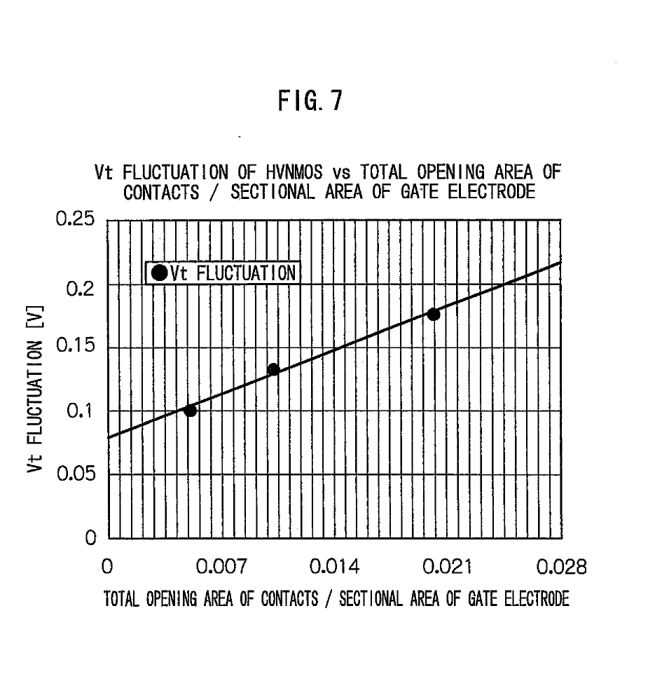

FIG. 4 shows operations in the first via hole etching step in the PMOS transistor in the high-voltage-withstanding semiconductor device of the invention.

In the high-voltage-withstanding semiconductor device of the invention, a forward diode 70 is formed as shown in FIG. 4 by forming a gate insulating film 59 and a gate electrode 60 on a n-well region 58, forming a source region 61 and a drain region 62 on the surface of the n-well region 58 on the both sides of the gate electrode 60 and providing a p⁺ diffusion layer 63 in a region other than an active region composed of the source region 61, the drain region 62 and a n-channel region 74 under the gate insulating film 59.

Next, an intermediary layer 67 is deposited on the substrate on which the gate electrode 60 has been formed and contacts 64 are provided after forming contact holes by a method such as plasma etching.

The source region 61 is connected to a first metal wire 65A via the contact 64, the drain region 62 is connected to a first metal wire 65C via the contact 64, and gate electrode 60 and the p⁺ diffusion layer 63 are connected to a first metal wire 65B via the contact 64.

First via holes 66 are formed on the first metal wires 65A, 6513 and 65C. The gate electrode 60 is insulated from the first metal wires 65A, 65B and 65C by the intermediary film 67 and the first metal wires 65A, 65B and 65C and the first via hole 66 are covered by the first interlayer film 68.

In the high-voltage-withstanding semiconductor device of the invention, the gate electrode 60 is directly connected with a forward diode 70 via the contact 64 and the first metal wire 65B.

An electric current 69 generated during the plasma etching enters from the first metal wire 65B and passes in order of the contact 64 and the forward diode 70. Accordingly, the current generated during the plasma etching does not pass through the gate electrode 60, so that it is possible to avoid the influence of the plasma damage that is the cause of the Vt fluctuation.

The present embodiment suppresses the Vt fluctuation of the transistor because it can avoid the plasma damage generated in forming the first via hole by the forward diode. Still more, the present embodiment equalizes the Vt fluctuation caused by the plasma damage generated in forming the contact holes among the transistors and avoids an operational failure of the high-voltage-withstanding semiconductor device that is otherwise caused by the variation of the threshold value Vt among the transistors.

Noted that it is needless to say that the high-voltage-withstanding semiconductor device and the method for fabricating the same described in the aforementioned embodiments should not be construed to be definitive and may be practiced within a scope meeting the requirement of the invention.

What is claimed is:

1. A high-voltage-withstanding semiconductor device, wherein a gate electrode of a transistor having a gate insulating film formed on a semiconductor substrate and having a thickness of 350 Å or more and a diode composed of a first conductive well region formed in a surface layer region of the semiconductor substrate and a second conductive diffusion layer formed in the surface layer region of the semiconductor substrate and on the well region are electrically connected by a wire directly connected to contacts formed respectively on the gate electrode and the diode, via the contacts.

2. A high-voltage-withstanding semiconductor device, comprising:
a semiconductor substrate;
transistors each having a first conductive channel region formed in a surface layer region of the semiconductor substrate, second conductive source and drain regions formed on both sides of the channel region, a gate insulating film formed on the channel region and having a thickness of 350 Å or more and a gate electrode formed on the gate insulating film;
a diode composed of a first conductive well region formed in the surface layer region of the semiconductor substrate and a second conductive diffusion layer formed in the surface layer region of the semiconductor substrate and on the well region;
contacts formed respectively on the gate electrode and on the second conductive diffusion layer; and
a wire, formed in the same wiring layer on the respective contacts, for electrically connecting the respective contacts.

3. The high-voltage-withstanding semiconductor device according to claim 1, wherein a difference in area ratios of an area of a part of the gate electrode contacting with the gate insulating film to a total opening area of contact holes formed on the gate electrode among the transistors having the gate oxide film of a thickness of 350 Å or more falls within a range of −5.0% to 5.0%.

4. The high-voltage-withstanding semiconductor device according to claim 2, wherein in area ratios of an area of a part of the gate electrode contacting with the gate insulating film to a total opening area of contact holes formed on the gate electrode among the transistors having the gate oxide film of a thickness of 350 Å or more falls within a range of −5.0% to 5.0%.

5. The high-voltage-withstanding semiconductor device according to claim 1, wherein the gate electrode is drawn to a region other than an active region composed of a source region, a drain region and the channel region under the gate insulating film, and the contact is formed on the drawn gate electrode.

6. The high-voltage-withstanding semiconductor device according to claim 2, wherein the gate electrode is drawn to a region other than an active region composed of the source region, the drain region and the channel region under the gate insulating film, and the contact is formed on the drawn gate electrode.

7. A method for fabricating a high-voltage-withstanding semiconductor device, comprising:
preparing a semiconductor substrate having a first conductive transistor forming region and a first conductive diode forming region;
forming a transistor by forming a first conductive channel region in a surface layer region of the semiconductor substrate in the transistor forming region, forming a gate insulating film having a thickness of 350 Å or more on the channel region, forming a gate electrode on the gate insulating film and forming second conductive source and drain regions on both sides of the channel region;
forming a diode by forming a second conductive diffusion layer in the surface layer region of the semiconductor substrate in the diode forming region;
forming contacts respectively on the gate electrode and on the second conductive diffusion layer; and
forming a wire for electrically connecting the respective contacts in the same wiring layer on the respective contacts.
